(19) United States
(12) Patent Application Publication
(10) Pub. No.: US 2025/0092570 A1
(43) Pub. Date: Mar. 20, 2025

(54) SILICON CARBIDE CRYSTAL GROWTH SYSTEM AND METHOD THEREOF

(71) Applicant: TAISIC MATERIALS CORP., TAOYUAN CITY (TW)

(72) Inventors: Dai-Liang MA, TAOYUAN CITY (TW); Bang-Ying YU, TAOYUAN CITY (TW); Bo-Cheng LIN, TAOYUAN CITY (TW)

(21) Appl. No.: 18/885,752

(22) Filed: Sep. 16, 2024

Related U.S. Application Data
(60) Provisional application No. 63/583,592, filed on Sep. 19, 2023.

(30) Foreign Application Priority Data
Jun. 28, 2024 (TW) 113124357

(51) Int. Cl. C30B 29/36; C30B 23/00; C30B 23/06

(52) U.S. Cl. CPC C30B 29/36; C30B 23/002; C30B 23/066

(57) ABSTRACT

Disclosed is a silicon carbide crystal growth system including a crucible, a heating device and a seed holder. The crucible includes a crucible body and a crucible cover covering the crucible body. The heating device includes a quartz tube and an induction coil spirally wound on an outer wall of the quartz tube. The crucible is disposed in the quartz tube. The crucible is disposed coaxially with the quartz tube. The seed holder is disposed on the crucible cover and includes a seed holding surface for holding an off-axis seed and is perpendicular to a central axis of the crucible, and an angle between a normal direction of the induction coil and a growth direction of the off-axis seed is between 0 degrees and 10 degrees, so that a silicon carbide crystal grows from the off-axis seed along isotherms provided by the induction coil, thereby obtaining a silicon carbide boule.

### CROSS REFERENCE TO RELATED PRESENT DISCLOSURE

This application claims the priority benefit of Taiwan Patent Application Serial Number 113124357, filed on Jun. 28, 2024 and the benefit of U.S. Provisional Application No. 63/583,592, filed Sep. 19, 2023, the entire contents of which are hereby incorporated by reference herein.

### TECHNICAL FIELD

The present disclosure relates to a silicon carbide boule manufacturing technique, in particular to a silicon carbide crystal growth system and a silicon carbide crystal growth method capable of growing a high-quality normal-axis silicon carbide crystal using an off-axis seed.

### RELATED ART

Silicon carbide has the characteristics of wide energy gap, high thermal conductivity, high electron saturation mobility and high chemical stability. Therefore, silicon carbide is widely used in power electronics, radio frequency devices, optoelectronic devices and other fields.

Methods for preparing silicon carbide boule comprise liquid phase epitaxy (LPE), chemical vapor deposition (CVD) and physical vapor transport (PVT), wherein the physical vapor transport method is the most common method of growing a silicon carbide crystal.

In the physical vapor transport method, the growth surface of the on-axis seed has fewer regular growth points, and in order to avoid affecting the quality of the prepared silicon carbide boule (e.g., defect rate), and further affecting the performance of the wafers and semiconductor devices made from the silicon carbide boule, so the silicon carbide boule is not usually prepared with the on-axis seed. Therefore, how to provide a silicon carbide crystal growth system and a silicon carbide crystal growth method to prepare the high-quality silicon carbide boule using the off-axis seed is an issue that needs to be solved urgently.

### SUMMARY

The embodiments of the present disclosure provide a silicon carbide crystal growth system and a silicon carbide crystal growth method, which can prepare the high-quality silicon carbide boule using the off-axis seed.

To solve the above technical problem, the present disclosure is implemented as follows:

The present disclosure provides a silicon carbide crystal growth system, which includes a crucible, a heating device and a seed holder. The crucible includes a crucible body and a crucible cover, the crucible body has an internal space for accommodating a raw material, and the crucible cover covers the crucible body. The heating device includes an induction coil and a quartz tube, the induction coil is spirally wound on an outer wall of the quartz tube, the crucible is disposed in the quartz tube, and the crucible is disposed coaxially with the quartz tube. The seed holder is disposed on the crucible cover and includes a seed holding surface. The seed holding surface is configured to hold an off-axis seed and is perpendicular to a central axis of the crucible, and an angle between a normal direction of the induction coil and a growth direction of the off-axis seed is between 0 degrees and 10 degrees, so that a silicon carbide crystal grows from a growth surface of the off-axis seed along isotherms of a thermal field provided by the induction coil, thereby obtaining a silicon carbide boule.

The present disclosure provides a silicon carbide crystal growth method, which includes the following steps: providing the silicon carbide crystal growth system of the present disclosure; after placing the raw material in the internal space of the crucible body and fixing the off-axis seed on the seed holding surface of the seed holder, covering the crucible body with the crucible cover and placing the crucible into the quartz tube; and applying a growth pressure and a growth temperature to the crucible to make a silicon carbide crystal grow from the growth surface of the off-axis seed along the isotherms of the thermal field provided by the induction coil, thereby obtaining the silicon carbide boule.

In the silicon carbide crystal growth system and the silicon carbide crystal growth method of the embodiments of the present disclosure, the seed holding surface for holding the off-axis seed is perpendicular to the central axis of the crucible, the crucible is disposed coaxially with the quartz tube, and the angle between the normal direction of the induction coil spirally wound on the quartz tube and the growth direction of the off-axis seed is between 0 degrees and 10 degrees, so that the silicon carbide crystal grow from the growth surface of the off-axis seed along the isotherms of the thermal field provided by the induction coil during the crystal growth process, thereby achieving uniform growth of the off-axis crystal and growing the high-quality and high-yield on-axis crystal to prepare a high-quality silicon carbide boule.

### BRIEF DESCRIPTION OF THE DRAWINGS

Accompanying drawings described herein are intended to provide a further understanding of the present disclosure and form a part of the present disclosure, and exemplary embodiments of the present disclosure and descriptions thereof are intended to explain the present disclosure but are not intended to unduly limit the present disclosure. In the drawings:

FIG. 1 is a schematic diagram of a silicon carbide crystal growth system according to an embodiment of the present disclosure;

FIG. 2 is a schematic cross-sectional view of an embodiment of the silicon carbide crystal growth system of FIG. 1;

FIG. 3 is an enlarged view of the area A in FIG. 2;

FIG. 4 is a method flow chart of a silicon carbide crystal growth method according to an embodiment of the present disclosure; and

FIG. 5 is a flow chart of an embodiment of step S430 in FIG. 4.

### DETAILED DESCRIPTION OF THE EMBODIMENTS

The embodiments of the present disclosure will be described below in conjunction with the relevant drawings. In the figures, the same reference numbers refer to the same or similar components or method flows.

It must be understood that the words “including”, “comprising” and the like used in this specification are used to indicate the existence of specific technical features, values, method steps, work processes, elements and/or components. However, it does not exclude that more technical features, values, method steps, work processes, elements, components, or any combination of the above can be added.

It must be understood that when an element is described as being “connected” or “coupled” to another element, it may be directly connected or coupled to another element, and intermediate elements therebetween may be present. In contrast, when an element is described as “directly connected” or “directly coupled” to another element, there is no intervening element therebetween.

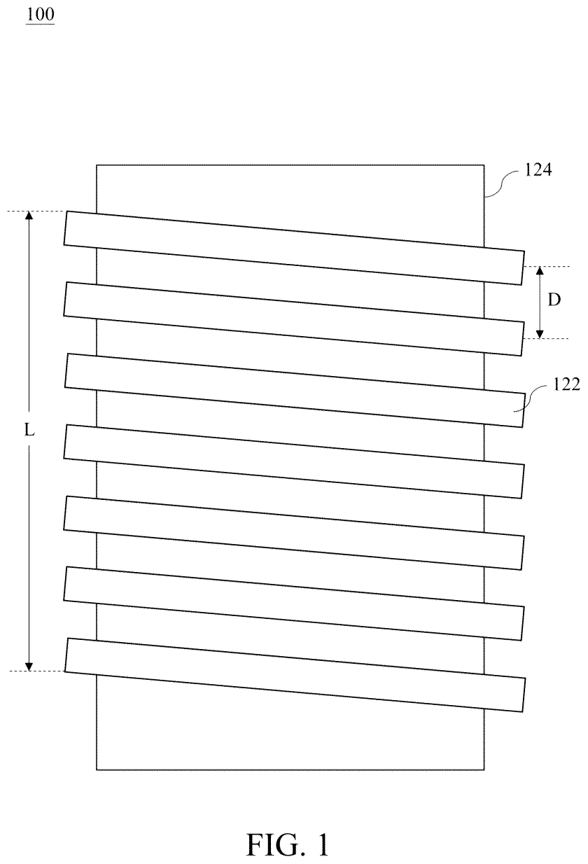

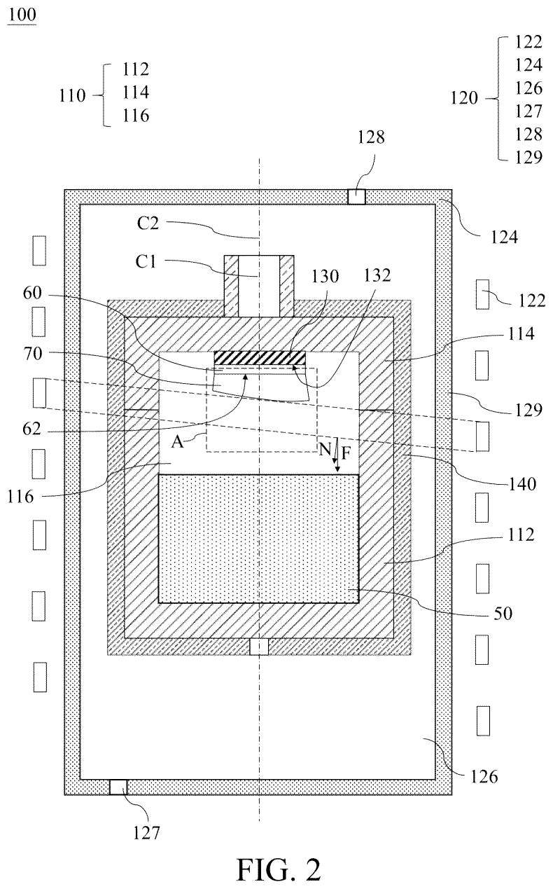

Please refer to FIG. 1 and FIG. 2, FIG. 1 is a schematic diagram of a silicon carbide crystal growth system according to an embodiment of the present disclosure, and FIG. 2 is a schematic cross-sectional view of an embodiment of the silicon carbide crystal growth system of FIG. 1. As shown in FIG. 1 and FIG. 2, a silicon carbide crystal growth system 100 comprises a crucible 110, a heating device 120 and a seed holder 130.

The crucible 110 comprises a crucible body 112 and a crucible cover 114. The crucible body 112 has an internal space 116 for accommodating a raw material 50. The crucible cover 114 covers the crucible body 112. The crucible 110 may be, but is not limited to, a graphite crucible; the raw material 50 may comprise, but is not limited to, silicon and/or silicon carbide, and carbon; The raw material 50 may be in a form of, but not limited to, powder, granules, or blocks, the purity of the raw material 50 may be greater than 99.99%, and the crystal phase of the raw material 50 may be, but is not limited to, α phase or β phase. This embodiment is not intended to limit the present disclosure.

The heating device 120 comprises an induction coil 122 and a quartz tube 124. The induction coil 122 is spirally wound on an outer side wall 129 of the quartz tube 124. The crucible 110 is disposed in the quartz tube 124. The crucible 110 is disposed coaxially with the quartz tube 124 (that is, a central axis C1 of the crucible 110 coincides with a central axis C2 of the quartz tube 124). The quartz tube 124 may have a cavity 126 and be provided with a first gas port 127 and a second gas port 128. The first gas port 127 is used to connect a vacuum pumping device (not drawn), and the second gas port 128 is used to connect a gas supply device (not drawn), and the vacuum pumping device and the gas supply device can be disposed outside the quartz tube 124. The crucible 110 is disposed in the cavity 126 of the quartz tube 124. The induction coil 122 may be made by spirally winding a copper tube and is a heating coil. The position of the induction coil 122 spirally wound on the outer wall 129 of the quartz tube 124 corresponds to the position of the crucible 110 disposed in the quartz tube 124, so that the heating device 120 heats the crucible 110 through the induction coil 122. This embodiment is not intended to limit the present disclosure.

The seed holder 130 is disposed on the crucible cover 114 and comprises a seed holding surface 132. The seed holding surface 132 is configured to hold the off-axis seed 60 and is perpendicular to the central axis C1 of the crucible 110, and an angle between a normal direction N of the induction coil 122 and a growth direction F of the off-axis seed 60 is between 0 degrees and 10 degrees (that is, the normal direction N of the induction coil 122 is located between positive and negative angles of 10 degrees with respect to the growth direction F of the off-axis seed 60), so that the silicon carbide crystal grows from the growth surface 62 of the off-axis seed 60 along the isotherms of the thermal field provided by the induction coil 122, thereby obtaining the silicon carbide boule 70. Among them, the seed holder 130 may be made of graphite; when the seed holder 130 and the crucible cover 114 are both made of graphite, the seed holder 130 may be integrally formed with the crucible cover 114. The off-axis seed 60 may be attached to the seed holding surface 132 of the seed holder 130. Specifically, the seed holder 130 may bond the off-axis seed 60 to the seed holding surface 132 through an adhesive layer (not shown), and the adhesive layer comprises graphite filler and carbide (e.g., phenolic resin) and may have low porosity. The growth surface 62 of the off-axis seed 60 is 1 degree to 10 degrees off-axis with respect to (0001) plane of the off-axis seed 60 (i.e., deviation from c-axis 1 degree to 10 degrees). When the off-axis seed 60 is fixed on the seed holder 130 and the crucible cover 114 covers the crucible body 112, there is a certain distance between the off-axis seed 60 and the raw material 50 placed in the internal space 116, and the growth surface 62 of the off-axis seed 60 faces the raw material 50. The off-axis seed 60 may be made of, but not limited to, silicon carbide. The diameter of the off-axis seed 60 may be, but not limited to, 6 inches (150 mm) or more. The normal direction N of the induction coil 122 refers to the direction perpendicular to the thread of the induction coil 122. The normal direction N of the induction coil 122 is toward the raw material 50. The growth direction F of the off-axis seed 60 refers to the direction from the off-axis seed 60 to the raw material 50. The growth direction F of the off-axis seed 60 is parallel to the central axis C1 of the crucible 110. A polytype of the silicon carbide boule is at least one of 4H, 6H, 3C and 15R. The silicon carbide crystal comprises p-type silicon carbide, n-type silicon carbide or semi-insulating silicon carbide.

In the situation where the seed holding surface 132 is perpendicular to the central axis C1 of the crucible 110 and the crucible 110 is disposed coaxially with the quartz tube 124, during the growth process of the silicon carbide crystal, by controlling the direction of the thermal field (that is, the induction coil 122 is spirally wound on an outer wall 129 of the quartz tube 124, and the angle between the normal direction N of the induction coil 122 and the growth direction F of the off-axis seed 60 is between 0 degrees and 10 degrees) and designing that the growth surface 62 of the off-axis seed 60 is 1 degree to 10 degrees off-axis with respect to (0001) plane of the off-axis seed 60, the silicon carbide crystal grows from the growth surface 62 of the off-axis seed 60 along the isotherms of the thermal field provided by the induction coil 122, thereby achieving uniform growth of the off-axis crystal, maintaining the polytype of silicon carbide crystal, and growing a high-quality and high-yield on-axis crystal to prepare a high-quality silicon carbide boule.

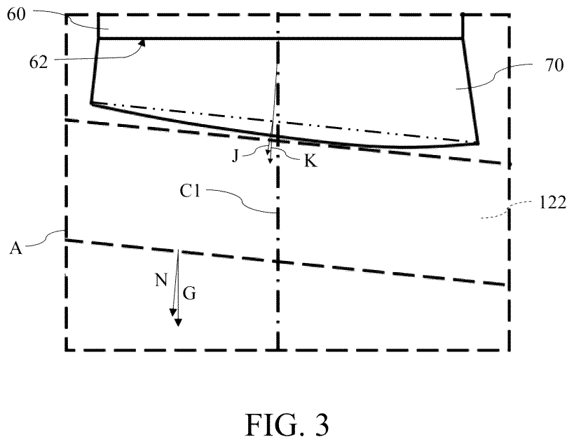

In one embodiment, an angle between a line J perpendicular to a connection line (i.e., the double-dotted chain line in FIG. 3) of two ends of a cross section of a surface of the silicon carbide boule 70 away from the off-axis seed 60 and a normal direction K of the off-axis seed 60 (i.e., off-axis orientation of the off-axis seed 60) is the same as an angle between the normal direction N of the induction coil 122 and a gravity direction G, as shown in FIG. 3, which is an enlarged view of the area A in FIG. 2. In another embodiment, there is a different between the angle between a line J perpendicular to the connection line of two ends of the cross section of the surface of the silicon carbide boule 70 away from the off-axis seed 60 and the normal direction K of the off-axis seed 60 and the angle between the normal direction N of the induction coil 122 and a gravity direction G within plus or minus 1 degree, and the difference mainly comes from the accumulation of tolerances in the assembly and processing of the silicon carbide crystal growth system 100 and the accumulated level tolerances of the holder for quartz tube 124, the holder for the crucible 110, etc. In other words, the angle between a line J perpendicular to the connection line of two ends of the cross section of the surface of the silicon carbide boule 70 away from the off-axis seed 60 and the normal direction K of the off-axis seed 60 is substantially equal to the angle between the normal direction N of the induction coil 122 and a gravity direction G.

In one embodiment, an axial length L (as shown in FIG. 1) of the induction coil 122 spirally wound on the quartz tube 124 may be, but is not limited to, 50 centimeters to 110 centimeters. Since the position where the induction coil 122 is spirally wound on the outer wall 129 of the quartz tube 124 corresponds to the position where the crucible 110 is disposed in the quartz tube 124, the axial length L may be greater than or equal to the length of the crucible 110 along the central axis C1. The axial length L may be regarded as the length that the heating device 120 can heat or the length of the uniform temperature area. The longer the axial length L, the larger the crystal growth area that allows the entire crucible 110 to be within the heating range. In addition, the crystal shape can be adjusted through the relative position of the crucible 110 (or seed) and the induction coil 122.

In one embodiment, a distance D (as shown in FIG. 1) between the centers of two adjacent turns in the induction coil 122 may be, but is not limited to, 30 millimeters to 100 millimeters.

In one embodiment, the number of turns of the induction coil 122 may be, but is not limited to, 6 turns to 13 turns. The more turns the induction coil 122 has, the denser the induction current is, and the greater the induction heat is. When the same power is used to heat the crucible 110 of the same size and the number of turns of the induction coil 122 is smaller, the temperature of the crucible 110 is lower due to less heating; however, the angle between the normal direction N of the induction coil 122 and the growth direction F is relatively large, so it can be applied to an off-axis crystal to grow a high-quality on-axis crystal.

In one embodiment, the silicon carbide crystal growth system 100 may further comprise a thermal insulation material 140, which is disposed outside the crucible body 112 and the crucible cover 114, as shown in FIG. 2. The thermal insulation material 140 may be, but is not limited to, a porous heat-insulating carbon material to achieve the effect of temperature maintenance.

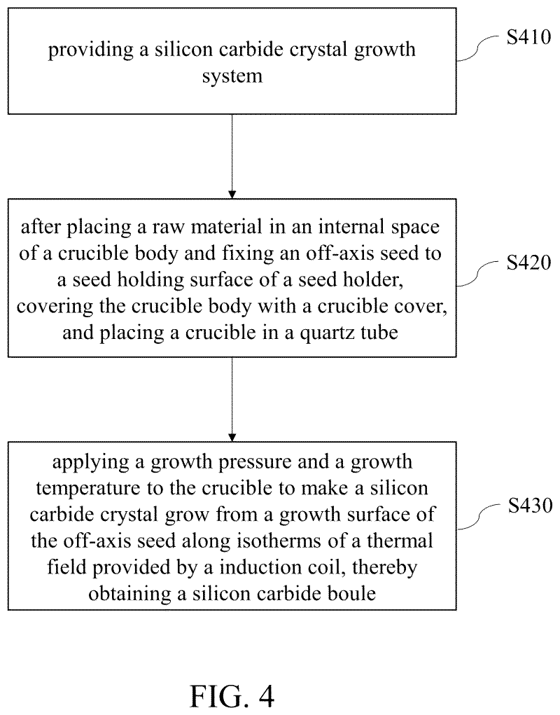

Please refer to FIG. 2 and FIG. 4, and FIG. 4 is a method flow chart of a silicon carbide crystal growth method according to an embodiment of the present disclosure. The silicon carbide crystal growth method of FIG. 4 can be applied to the silicon carbide crystal growth system 100 of FIG. 2. The silicon carbide crystal growing method in FIG. 4 comprises the following steps: providing a silicon carbide crystal growth system 100 (step S410); after placing a raw material 50 in an internal space 116 of a crucible body 112 and fixing an off-axis seed 60 to a seed holding surface 132 of a seed holder 130, covering the crucible body 112 with a crucible cover 114, and placing a crucible 110 in a quartz tube 124 (step S420); and applying a growth pressure and a growth temperature to the crucible 110 to make a silicon carbide crystal grow from a growth surface 62 of the off-axis seed 60 along isotherms of a thermal field provided by a induction coil 122, thereby obtaining a silicon carbide boule 70 (step S430).

In step S420, the raw material 50 is placed in the crucible body 112, and the off-axis seed 60 is fixed to the seed holding surface 132 of the seed holder 130 provided on the crucible cover 114, and then the crucible cover 114 covers the crucible body 122. Next, the crucible 110 is placed into the quartz tube 124. It should be noted that since the joint between the crucible cover 114 and the crucible body 112 is not sealed (that is, there is a gap (not shown) between the crucible cover 114 and the crucible body 112), the cavity 126 of the quartz tube 124 is communicated with the inside of the crucible 110 when the crucible 110 is placed in the quartz tube 124.

In step S430, the pressure in the crucible 110 can be set through the vacuum pumping device and the gas supply device, and the temperature of the crucible 110 can be set through the induction coil 122, so that the silicon carbide crystal may grow from the growth surface 62 of the off-axis seed 60 along the isotherms of the thermal field provided by the induction coil 122 when the pressure in the crucible 110 is the growth pressure and the temperature of the crucible 110 is the growth temperature.

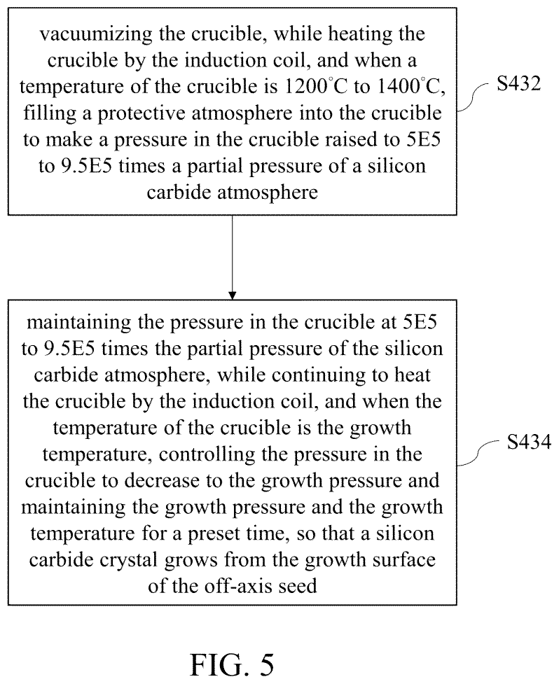

In an embodiment, please refer to FIG. 5, which is a flow chart of an embodiment of step S430 in FIG. 4. As shown in FIG. 5, step S430 may comprise: vacuumizing the crucible 110, while heating the crucible 110 by the induction coil 122, and when a temperature of the crucible 110 is 1200° C. to 1400° C., filling a protective atmosphere into the crucible 110 to make a pressure in the crucible 110 raised to 5E5 to 9.5E5 times a partial pressure of a silicon carbide atmosphere (step S432); and maintaining the pressure in the crucible 110 at 5E5 to 9.5E5 times the partial pressure of the silicon carbide atmosphere, while continuing to heat the crucible 110 by the induction coil 122, and when the temperature of the crucible 110 is the growth temperature, controlling the pressure in the crucible 110 to decrease to the growth pressure and maintaining the growth pressure and the growth temperature for a preset time, so that a silicon carbide crystal grows from the growth surface of the off-axis seed 60 (step S434).

In step S432, the quartz tube 124 is vacuumized by the vacuum pumping device through the first air port 127, the cavity 126 of the quartz tube 124 is communicated with the inside of the crucible 110, so the vacuum pumping device can remove air and other impurities from the interior of the cavity 126 of the quartz tube 124 and the crucible 110 through the first air port 127. The gas supply device fills the quartz tube 124 with a protective atmosphere through the second gas port 128, and the cavity 126 of the quartz tube 124 is communicated to the inside of the crucible 110, so the gas supply device can fill the cavity 126 of the quartz tube 124 and the interior of the crucible 120 with the protective atmosphere through the second gas port 128. By the vacuum pumping device and the gas supply device, when the temperature of the crucible 110 is 1200° C. to 1400° C., the pressure inside the cavity 126 of the quartz tube 124 and the crucible 110 can be controlled to rise to 5E5 times to 9.5E5 times the partial pressure of the silicon carbide atmosphere (approximately 50 kilopascal (kPa) to 95 kPa). When the temperature of the crucible 110 is 1200° C. to 1400° C., the quartz tube 124 is filled with the protective atmosphere, to make the pressure in the quartz tube 124 rises to 5E5 times to 9.5E5 times the partial pressure of the silicon carbide atmosphere, ensuring that silicon carbide of the off-axis seed 60 is not evaporated under this condition. The protective atmosphere may comprise, but is not limited to, argon or helium, and the flow range of argon or helium can be controlled from 100 to 1000 sccm (standard cubic centimeter per minute).

In step S434, when the pressure inside the quartz tube 124/the pressure inside the crucible 110 is between 0.5 torr and 100 torr, the temperature of the crucible 120 is the growth temperature, and the above conditions are maintained for the preset time, the raw material 50 can be sublimated and vaporized after being heated and deposited on the growth surface 62 of the off-axis seed 60 in the form of gas phase molecules. The growth temperature may be, but not limited to, 1950° C. to 2500° C., and the preset time may be, but is not limited to, 100 hours to 200 hours. However, this embodiment is not used to limit the present disclosure. The actual growth temperature and the preset time can be adjusted according to actual needs.

In addition, step S434 may comprise heating the crucible 110 by the induction coil 122 to control a top temperature of the crucible 110 to be the growth temperature and a bottom temperature of the crucible 110 to be higher than the top temperature of the crucible 110, and maintaining the top temperature and the bottom temperature of the crucible 110 for the preset time, so that the silicon carbide crystal grows from the off-axis seed 60. In other words, the temperature gradient of the crucible 110 can be controlled by the induction coil 122.

Please refer to Table 1 and Table 2 below. Table 1 and Table 2 show the maximum resistivity, the median resistivity and the minimum resistivity of each qualified wafer with a thickness of 600 microns obtained by the silicon carbide boules on the growth surface of off-axis seeds using the silicon carbide crystal growth system 1 (i.e., the silicon carbide crystal growth system with a 0-degree angle between the normal direction of the induction coil and the growth direction of the off-axis seed crystal) and the silicon carbide crystal growth system 2 (i.e., the silicon carbide crystal growth system with a 5-degree angle between the normal direction of the induction coil and the growth direction of the off-axis seed crystal) at growth temperatures of 2120° C. and 2125° C., growth pressures of 200 Pa and growth times of 150 hours, wherein each silicon carbide boule is sliced, polished and processed into multiple wafers, and then performing resistivity testing at multiple measuring points on each wafer after a surface cleaning process; the off-axis seeds are seeds that are deviated from the c-axis with 4 degrees; the qualified wafer refers to a wafer with a minimum resistivity greater than 1E+7 ohm-cm; the center thickness of the silicon carbide boule prepared by the silicon carbide crystal growth system 1 is 21 mm, and the center thickness of the silicon carbide boule prepared by the silicon carbide crystal growth system 2 is 25 mm; if the normal direction N of the induction coil 122 coincides with the growth direction F, the center thickness of the silicon carbide boule is the maximum thickness of the silicon carbide boule; if there is an angle between the normal direction N of the induction coil 122 and the growth direction F, the center thickness of the silicon carbide boule is the average thickness of the silicon carbide boule; the thickness of the on-axis silicon carbide ingot obtained by processing the silicon carbide boule prepared by the silicon carbide crystal growth system 1 is 9.15 mm to obtain 10 qualified wafers; the thickness of the on-axis silicon carbide ingot obtained by processing the silicon carbide boule prepared by the silicon carbide crystal growth system 2 is 18.5 mm to obtain 19 qualified wafers. In Table 1 and Table 2, the smaller the number of the qualified wafer is, the closer the qualified wafer is to the dome-side surface of the silicon carbide boule; the larger the number of the qualified wafer is, the closer the qualified wafer is to the seed-side surface of the silicon carbide boule.

TABLE 1

| Silicon carbide | Maximum | Median | Minimum |
|---|---|---|---|
| crystal growth | resistivity | resistivity | resistivity |
| system 1 | (ohm-cm) | (ohm-cm) | (ohm-cm) |
| Qualified wafer 1 | 5.32E+11 | 3.73E+11 | 9.04E+10 |
| Qualified wafer 2 | 5.43E+11 | 3.90E+11 | 9.20E+10 |
| Qualified wafer 3 | 5.25E+11 | 3.81E+11 | 9.12E+10 |
| Qualified wafer 4 | 5.15E+11 | 3.66E+11 | 9.05E+10 |
| Qualified wafer 5 | 4.83E+11 | 3.52E+11 | 8.46E+10 |
| Qualified wafer 6 | 5.37E+11 | 3.81E+11 | 9.28E+10 |
| Qualified wafer 7 | 5.06E+11 | 3.58E+11 | 8.60E+10 |
| Qualified wafer 8 | 5.29E+11 | 3.81E+11 | 8.54E+10 |
| Qualified wafer 9 | 5.72E+11 | 3.46E+11 | 6.86E+10 |
| Qualified wafer 10 | 5.84E+11 | 2.62E+11 | 5.90E+09 |

TABLE 2

| Silicon carbide | Maximum | Median | Minimum |
|---|---|---|---|
| crystal growth | resistivity | resistivity | resistivity |
| system 2 | (ohm-cm) | (ohm-cm) | (ohm-cm) |
| Qualified wafer 1 | 6.10E+11 | 4.24E+11 | 1.35E+11 |
| Qualified wafer 2 | 5.72E+11 | 3.74E+11 | 1.01E+11 |
| Qualified wafer 3 | 5.81E+11 | 4.06E+11 | 9.58E+10 |
| Qualified wafer 4 | 6.30E+11 | 4.26E+11 | 1.17E+11 |
| Qualified wafer 5 | 6.11E+11 | 3.33E+11 | 7.65E+10 |
| Qualified wafer 6 | 5.23E+11 | 2.91E+11 | 8.46E+10 |
| Qualified wafer 7 | 5.18E+11 | 3.26E+11 | 8.04E+10 |
| Qualified wafer 8 | 5.33E+11 | 3.46E+11 | 9.29E+10 |
| Qualified wafer 9 | 5.30E+11 | 3.31E+11 | 7.98E+10 |
| Qualified wafer 10 | 5.24E+11 | 3.22E+11 | 8.80E+10 |
| Qualified wafer 11 | 5.38E+11 | 3.17E+11 | 9.00E+10 |
| Qualified wafer 12 | 5.30E+11 | 3.29E+11 | 9.28E+10 |
| Qualified wafer 13 | 5.20E+11 | 3.30E+11 | 9.16E+10 |
| Qualified wafer 14 | 5.21E+11 | 3.22E+11 | 9.01E+10 |
| Qualified wafer 15 | 5.29E+11 | 3.15E+11 | 8.74E+10 |
| Qualified wafer 16 | 5.29E+11 | 3.29E+11 | 8.72E+10 |
| Qualified wafer 17 | 4.88E+11 | 3.11E+11 | 8.79E+10 |
| Qualified wafer 18 | 5.19E+11 | 3.54E+11 | 9.68E+10 |
| Qualified wafer 19 | 5.46E+11 | 3.80E+11 | 1.14E+11 |

From the above, it can be seen that when the on-axis silicon carbide ingot is obtained from the silicon carbide boule prepared by the silicon carbide crystal growth system 1, there is a thickness loss of 11.85 mm, while when the on-axis silicon carbide ingot obtained from the silicon carbide boule prepared by the silicon carbide crystal growth system 2, there is a thickness loss of 6.5 mm; and the number of qualified wafers obtained from the silicon carbide ingot prepared by the silicon carbide crystal growth system 1 is less than the number of qualified wafers obtained from the silicon carbide ingot prepared by the silicon carbide crystal growth system 2. Therefore, the silicon carbide crystal growth system of the present disclosure can be used to grow a near-on-axis crystal on the off-axis seed, maintain the polytype of the silicon carbide crystal, and improve the yield of processing the off-axis crystal into the on-axis crystal, achieving quality improvement and cost reduction.

To sum up, in the embodiments of the present disclosure, the seed holding surface for holding the off-axis seed is perpendicular to the central axis of the crucible, the crucible is disposed coaxially with the quartz tube, and the angle between the normal direction of the induction coil spirally wound on the quartz tube and the growth direction of the off-axis seed is between 0 degrees and 10 degrees, so that the silicon carbide crystal grows from the growth surface of the off-axis seed along the isotherms of the thermal field provided by the induction coil during the crystal growth process, thereby achieving uniform growth of the off-axis crystal and growing a high-quality and high-yield on-axis crystal to prepare a high-quality silicon carbide boule.

While the present disclosure is disclosed in the foregoing embodiments, it should be noted that these descriptions are not intended to limit the present disclosure. On the contrary, the present disclosure covers modifications and equivalent arrangements obvious to those skilled in the art. Therefore, the scope of the claims must be interpreted in the broadest manner to comprise all obvious modifications and equivalent arrangements.

What is claimed is:

1. A silicon carbide crystal growth system, comprising:
a crucible comprising a crucible body and a crucible cover, wherein the crucible body has an internal space for accommodating a raw material, the crucible cover covers the crucible body;
a heating device comprising an induction coil and a quartz tube, wherein the induction coil is spirally wound on an outer wall of the quartz tube, the crucible is disposed in the quartz tube, and the crucible is disposed coaxially with the quartz tube; and
a seed holder disposed on the crucible cover and comprising a seed holding surface, wherein the seed holding surface is configured to hold an off-axis seed and is perpendicular to a central axis of the crucible, and an angle between a normal direction of the induction coil and a growth direction of the off-axis seed is between 0 degrees and 10 degrees, so that a silicon carbide crystal grows from a growth surface of the off-axis seed along isotherms of a thermal field provided by the induction coil, thereby obtaining a silicon carbide boule.

2. The silicon carbide crystal growth system according to claim 1, wherein an axial length of the induction coil spirally wound on the quartz tube is 50 centimeters to 110 centimeters.

3. The silicon carbide crystal growth system according to claim 1, wherein a distance between centers of two adjacent turns in the induction coil is 30 millimeters to 100 millimeters.

4. The silicon carbide crystal growth system according to claim 1, wherein the number of turns of the induction coil is 6 turns to 13 turns.

5. The silicon carbide crystal growth system according to claim 1, wherein an angle between a line perpendicular to a connection line of two ends of a cross section of a surface of the silicon carbide boule away from the off-axis seed and a normal direction of the off-axis seed is substantially equal to an angle between the normal direction of the induction coil and a gravity direction.

6. The silicon carbide crystal growth system according to claim 1, further comprising a thermal insulation material disposed outside the crucible body and the crucible cover.

7. A silicon carbide crystal growth method, comprising the following steps:
(a) providing a silicon carbide crystal growth system according to claim 1;
(b) after placing the raw material in the internal space of the crucible body and fixing the off-axis seed to the seed holding surface of the seed holder, covering the crucible body with the crucible cover, and placing the crucible in the quartz tube; and
(c) applying a growth pressure and a growth temperature to the crucible to make the silicon carbide crystal grow from the growth surface of the off-axis seed along the isotherms of the thermal field provided by the induction coil, thereby obtaining the silicon carbide boule.

8. The silicon carbide crystal growth method according to in claim 7, wherein the growth pressure is between 1 torr and 100 torr.

9. The silicon carbide crystal growth method according to claim 7, wherein the growth temperature is 1950° C. to 2500° C.

10. The silicon carbide crystal growth method according to claim 7, wherein the step (c) comprises the following steps:
(c1) vacuumizing the crucible, while heating the crucible by the induction coil, and when a temperature of the crucible is 1200° C. to 1400° C., filling a protective atmosphere into the crucible to make a pressure in the crucible raised to 5E5 to 9.5E5 times a partial pressure of a silicon carbide atmosphere; and
(c2) maintaining the pressure in the crucible at 5E5 to 9.5E5 times the partial pressure of the silicon carbide atmosphere, while continuing to heat the crucible by the induction coil, and when the temperature of the crucible is the growth temperature, controlling the pressure in the crucible to decrease to the growth pressure and maintaining the growth pressure and the growth temperature for a preset time, so that the silicon carbide crystal grows from the growth surface of the off-axis seed.

11. The silicon carbide crystal growth method according to claim 10, wherein the growth pressure is between 1 torr and 100 torr.

12. The silicon carbide crystal growth method according to claim 10, wherein the growth temperature is 1950° C. to 2500° C.

13. The silicon carbide crystal growth method according to claim 10, wherein the preset time is 100 hours to 200 hours.

14. The silicon carbide crystal growth method according to claim 10, wherein the protective atmosphere comprises argon or helium.

15. The silicon carbide crystal growth method according to claim 10, the step (c2) comprises:
heating the crucible by the induction coil to control a top temperature of the crucible to be the growth temperature and a bottom temperature of the crucible to be higher than the top temperature of the crucible, and maintaining the top temperature and the bottom temperature of the crucible for the preset time, so that the silicon carbide crystal grows from the off-axis seed.

16. The silicon carbide crystal growth method according to claim 7, wherein a polytype of the silicon carbide boule is at least one of 4H, 6H, 3C and 15R.

17. The silicon carbide crystal growth method according to claim 7, wherein the growth surface of the off-axis seed is 1 degree to 10 degrees off-axis with respect to the (0001) plane of the off-axis seed.
